(19) United States
(12) Patent Application Publication
(10) Pub. No.: US 2007/0292245 A1
(43) Pub. Date: Dec. 20, 2007

(54) Stage assembly with secure device holder

(75) Inventors: Alton H. Phillips, East Palo Alto, CA (US); Douglas C. Watson, Campbell, CA (US); Leonard Wai Fung Kho, San Francisco, CA (US); Hiromitsu Yoshimoto, Saitama-shi (JP)

Correspondence Address: THE LAW OFFICE OF STEVEN G ROEDER, 5560 CHELSEA AVE, LA JOLLA, CA, 92037, US

(73) Assignee: Nikon Corporation, Tokyo (JP)

(21) Appl. No.: 11/805,806

(22) Filed: May 24, 2007

Related U.S. Application Data
(60) Provisional application No. 60/808,378, filed on May 25, 2006.

(51) Int. Cl. H01L 21/44

(52) U.S. Cl. 414/222.01

(57) ABSTRACT

A stage assembly (18) that moves a work piece (200) includes a stage base (36), a stage (238), and a stage mover assembly (40) that moves the stage (238) relative to the stage base (36). The stage (238) includes a stage housing (244) and a device holder (242). The stage housing (244) is rigid. The device holder (242) selectively secures the work piece (200) to the stage housing (244). The device holder (242) can included one or more support pairs (250) that clamp the work piece (200) there between to couple the work piece (200) to the stage housing (244). The stage (238) can include one or more resilient supports (258) that support the work piece (200). Further, the support pairs (250) can retain the work piece (200) so that a small fluid gap exists between the work piece (200) and the stage (238) so that the work piece (200) experiences squeeze film damping.

### RELATED APPLICATION

This application claims priority on U.S. Provisional Application Ser. No. 60/808,378, filed on May 25, 2006, and entitled “Reticle Chuck”. The contents of U.S. Provisional Application Ser. No. 60/808,378. are incorporated herein by reference.

### BACKGROUND

Exposure apparatuses for semiconductor processing are commonly used to transfer images from a reticle onto a semiconductor wafer during semiconductor processing. A typical exposure apparatus includes an illumination source, a reticle stage assembly that holds and positions a reticle, an optical assembly, a wafer stage assembly that holds and positions a semiconductor wafer, a measurement system, and a control system.

One type of stage assembly includes a stage base, a stage that includes a device holder that retains the wafer or the reticle, and a stage mover assembly that moves the stage and the wafer or the reticle. One type of device holder is a vacuum type chuck that uses a vacuum to pull the device against the stage. More specifically, in this design, the stage includes one or more channels and the device is positioned above the channels. Subsequently, a vacuum is created in the channels to pull the device against the stage.

Unfortunately, any flatness mismatch between the stage and the device distorts the device when the device is pulled against the stage. The amount of distortion will vary according to the device. Accordingly, the resulting shape of the device is complicated and is not repeatable.

Further, movement of the stage and work piece can cause vibration of the work piece. This can reduce the quality of the images that are transferred to the wafer.

### SUMMARY

The present invention is directed a stage assembly that moves a work piece. The stage assembly includes a stage base, a stage, and a stage mover assembly that moves the stage relative to the stage base. The stage includes a stage housing and a device holder. The stage housing is rigid. The device holder selectively secures the work piece to the stage housing. In one embodiment, the device holder including a first support pair that clamp the work piece there between to couple the work piece to the stage housing. In certain embodiments, as a result of this design, the device holder retains the work piece in a secure and repeatable fashion.

Additionally, the device holder can include a second support pair and a third support pair that clamp the work piece there between to couple the work piece to the stage housing. With this design, the work piece is retained in a somewhat kinematic fashion to reduce distortion on the work piece caused by the device holder.

In one embodiment, the stage includes a first movable section that is movable relative to the stage housing. In this embodiment, the first support pair includes a lower support that is secured to the stage housing and an upper support that is secured to the movable section. Further, the movable section can be movable along a first axis to lift the upper support away from the work piece, and along a second axis to move the upper support from above the work piece. Moreover, the movable section can define a chamber. In this embodiment, a vacuum in the chamber moves the movable section along the first axis to clamp the work piece between the supports of the first support pair. Further, the movable section can include a section housing, a resilient member that urges the section housing along the first axis away from the work piece, and a seal that rests on the stage housing to seal the chamber.

In another embodiment, the stage can include one or more resilient supports that support the work piece. For example, the stage can include a plurality of resilient supports that support a first side and a second side of the work piece. With this design, in certain embodiments, the work piece is retained in a somewhat parabolic shape.

In yet another embodiment, the work piece is retained a relatively small fluid gap away from the stage housing with the first support pair so that the work piece experiences squeeze film damping.

In another embodiment, the stage assembly again includes the stage base, the stage, and the stage mover assembly. In this embodiment, the stage includes the stage housing and the resilient support that engages the work piece and supports the work piece away from the stage housing. In certain embodiments, the resilient support inhibits sagging of the work piece near the resilient support so that the work piece deforms in a controlled, repeatable fashion.

In still another embodiment, the stage assembly again includes the stage base, the stage, and the stage mover assembly. In this embodiment, the device holder secures the work piece to the stage housing, and the device holder maintains the work piece a relatively small fluid gap away from the stage. As a result thereof, the work piece experiences squeeze film type damping.

The present invention is also directed to method for moving a work piece. The method includes the steps of providing a stage base, retaining the work piece with a stage, and moving the stage with a stage mover assembly. In one embodiment the stage includes a stage housing, and a first support pair that selectively secures the work piece to the stage housing with the work piece clamped between the first support pair. In another embodiment, the stage includes a stage housing, a device holder that selectively secures the work piece to the stage housing, and a plurality of spaced apart resilient supports that support the work piece to inhibit sagging of the work piece. In yet another embodiment, the stage includes a stage housing, and a device holder that secures the work piece to the stage with a relatively small fluid gap away from the stage so that the work piece experiences squeeze film damping.

Further, the present invention is also directed to a wafer, and a method for manufacturing an object or a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an exposure apparatus having features of the present invention;

FIG. 2A is a simplified side plan view of a work piece and one embodiment of a device stage having features of the present invention with a portion of the device stage in a locked position;

FIG. 2B is a simplified side plan view of a work piece and one embodiment of a device stage having features of the present invention with a portion of the device stage in an unlocked position;

FIG. 2C is a simplified top plan view of the work piece and the device stage of FIG. 2A;

FIG. 2D is a simplified cut-away view taken on line 2D-2D in FIG. 2C;

FIG. 2E is a simplified cut-away view taken on line 2E-2E in FIG. 2D;

FIG. 2F is a simplified cut-away view taken on line 2F-2F in FIG. 2E;

FIG. 2G is a simplified cut-away view;

FIG. 3A is a top plan view of a portion of the device stage;

FIGS. 3B, 3C, 3D, 3E, and 3F are alternative cut-away views taken from FIG. 3A;

FIG. 4 is a simplified cut-away taken on line 4-4 in FIG. 2A;

FIG. 5 is an enlarged view taken on line 5-5 in FIG. 2F;

FIGS. 6A and 6B are alternative cut-away views of a portion of another embodiment of a stage assembly having features of the present invention and the work piece;

FIG. 7A is a simplified top plan view of a work piece and another embodiment of a device stage having features of the present invention;

FIG. 7B is a simplified side plan view of the work piece and the stage of FIG. 7A with a portion of the device stage illustrated in phantom in an unlocked position;

FIG. 8A is a flow chart that outlines a process for manufacturing a device in accordance with the present invention; and

FIG. 8B is a flow chart that outlines device processing in more detail.

### DESCRIPTION

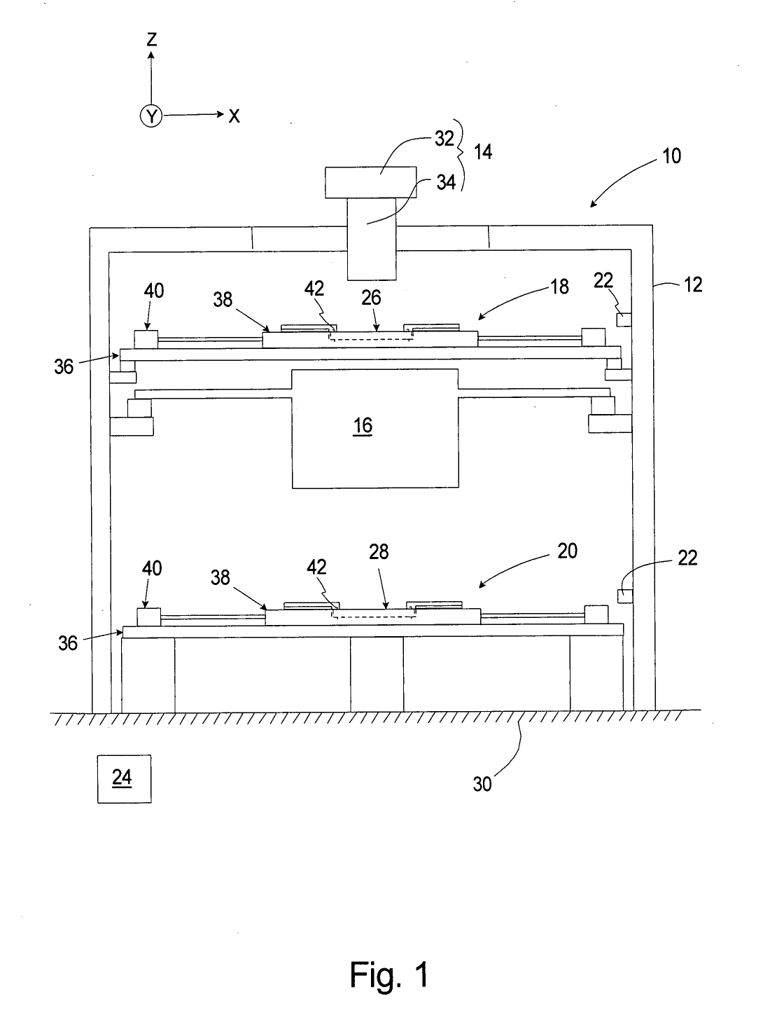

FIG. 1 is a schematic illustration of a precision assembly, namely an exposure apparatus 10 having features of the present invention. The exposure apparatus 10 includes an apparatus frame 12, an illumination system 14 (irradiation apparatus), an optical assembly 16, a reticle stage assembly 18, a wafer stage assembly 20, a measurement system 22, and a control system 24. The design of the components of the exposure apparatus 10 can be varied to suit the design requirements of the exposure apparatus 10.

A number of Figures include an orientation system that illustrates an X axis, a Y axis that is orthogonal to the X axis and a Z axis that is orthogonal to the X and Y axes. It should be noted that these axes can also be referred to as the first, second and third axes.

The exposure apparatus 10 is particularly useful as a lithographic device that transfers a pattern (not shown) of an integrated circuit from a reticle 26 onto a semiconductor wafer 28. The exposure apparatus 10 mounts to a mounting base 30, e.g., the ground, a base, or floor or some other supporting structure.

As an overview, in certain embodiments, the reticle stage assembly 18 retains the reticle 26 in a secure, repeatable fashion, supports the reticle 26 in an improved fashion, and/or inhibits vibration of the reticle 26.

There are a number of different types of lithographic devices. For example, the exposure apparatus 10 can be used as a scanning type photolithography system that exposes the pattern from the reticle 26 onto the wafer 28 with the reticle 26 and the wafer 28 moving synchronously. In a scanning type lithographic device, the reticle 26 is moved perpendicularly to an optical axis of the optical assembly 16 by the reticle stage assembly 18 and the wafer 28 is moved perpendicularly to the optical axis of the optical assembly 16 by the wafer stage assembly 20. Scanning of the reticle 26 and the wafer 28 occurs while the reticle 26 and the wafer 28 are moving synchronously.

Alternatively, the exposure apparatus 10 can be a step-and-repeat type photolithography system that exposes the reticle 26 while the reticle 26 and the wafer 28 are stationary. In the step and repeat process, the wafer 28 is in a constant position relative to the reticle 26 and the optical assembly 16 during the exposure of an individual field. Subsequently, between consecutive exposure steps, the wafer 28 is consecutively moved with the wafer stage assembly 20 perpendicularly to the optical axis of the optical assembly 16 so that the next field of the wafer 28 is brought into position relative to the optical assembly 16 and the reticle 26 for exposure. Following this process, the images on the reticle 26 are sequentially exposed onto the fields of the wafer 28, and then the next field of the wafer 28 is brought into position relative to the optical assembly 16 and the reticle 26.

However, the use of the exposure apparatus 10 provided herein is not limited to a photolithography system for semiconductor manufacturing. The exposure apparatus 10, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern from a mask to a substrate with the mask located close to the substrate without the use of a lens assembly.

The apparatus frame 12 is rigid and supports the components of the exposure apparatus 10. The apparatus frame 12 illustrated in FIG. 1 supports the reticle stage assembly 18, the optical assembly 16 and the illumination system 14 above the mounting base 30.

The illumination system 14 includes an illumination source 32 and an illumination optical assembly 34. The illumination source 32 emits a beam (irradiation) of light energy. The illumination optical assembly 34 guides the beam of light energy from the illumination source 32 to the optical assembly 16. The beam illuminates selectively different portions of the reticle 26 and exposes the wafer 28. In FIG. 1, the illumination source 32 is illustrated as being supported above the reticle stage assembly 18. Alternatively, the illumination source 32 can be secured to one of the sides of the apparatus frame 12 and the energy beam from the illumination source 32 is directed to above the reticle stage assembly 18 with the illumination optical assembly 34. Still alternatively, the energy beam can be directed at the bottom of the reticle 26.

The illumination source 32 can be a g-line source (436 nm), an i-line source (365 nm), a KrF excimer laser (248 nm), an ArF excimer laser (193 nm) or a F₂ laser (157 nm). Alternatively, the illumination source 32 can generate charged particle beams such as an x-ray or an electron beam. For instance, in the case where an electron beam is used, thermionic emission type lanthanum hexaboride (LaB₆) or tantalum (Ta) can be used as a cathode for an electron gun. Furthermore, in the case where an electron beam is used, the structure could be such that either a mask is used or a pattern can be directly formed on a substrate without the use of a mask.

The optical assembly 16 projects and/or focuses the light from the reticle 26 to the wafer 28. Depending upon the design of the exposure apparatus 10, the optical assembly 16 can magnify or reduce the image illuminated on the reticle 26. The optical assembly 16 need not be limited to a reduction system. It could also be a 1× or magnification system.

When far ultra-violet rays such as the excimer laser is used, glass materials such as quartz and fluorite that transmit far ultra-violet rays can be used in the optical assembly 16. When the F₂ type laser or x-ray is used, the optical assembly 16 can be either catadioptric or refractive (a reticle should also preferably be a reflective type), and when an electron beam is used, electron optics can consist of electron lenses and deflectors. The optical path for the electron beams should be in a vacuum.

Also, with an exposure device that employs vacuum ultra-violet radiation (VUV) of wavelength 200 nm or lower, use of the catadioptric type optical system can be considered. Examples of the catadioptric type of optical system include the disclosure Japan Patent Application Disclosure No. 8-171054 published in the Official Gazette for Laid-Open Patent Applications and its counterpart U.S. Pat. No. 5,668,672, as well as Japan Patent Application Disclosure No. 10-20195 and its counterpart U.S. Pat. No. 5,835,275. In these cases, the reflecting optical device can be a catadioptric optical system incorporating a beam splitter and concave mirror. Japan Patent Application Disclosure No. 8-334695 published in the Official Gazette for Laid-Open Patent Applications and its counterpart U.S. Pat. No. 5,689,377 as well as Japan Patent Application Disclosure No. 10-3039 and its counterpart U.S. patent application Ser. No. 873,605 (Application Date: Jun. 12, 1997) also use a reflecting-refracting type of optical system incorporating a concave mirror, etc., but without a beam splitter, and can also be employed with this invention. As far as is permitted, the disclosures in the above-mentioned U.S. patents, as well as the Japan patent applications published in the Official Gazette for Laid-Open Patent Applications are incorporated herein by reference.

The reticle stage assembly 18 holds and positions the reticle 26 relative to the optical assembly 16 and the wafer 28. Somewhat similarly, the wafer stage assembly 20 holds and positions the wafer 28 with respect to the projected image of the illuminated portions of the reticle 26.

The design of each stage assembly 18, 20 can vary pursuant to the teaching provided herein. In one embodiment, each stage assembly 18, 20 includes a stage base 36, a stage 38, and a stage mover assembly 40. The size, shape, and design of each these components can be varied.

In FIG. 1, for each stage assembly 18, 20, the stage base 36 supports and guides the movement of the stage 38 along the X axis, along the Y axis and about the Z axis. In one embodiment, the stage base 36 can be generally rectangular shaped. Further, a bearing (not shown) can support the stage 38 above the stage base 36 and allow the stage 38 to move relative to the stage base 36 along the X axis, along the Y axis and about the Z axis.

The stage 38 retains the device. In one embodiment, the stage 38 is generally rectangular shaped and includes a device holder 42 for holding the reticle 26 or the wafer 28. The stage 38 and the device holder 42 are described in more detail below.

The stage mover assembly 40 moves the stage 38 relative to the stage base 36. In certain embodiments, the stage mover assembly 40 moves the stage 38 with three degrees of freedom, namely, along the X axis, along the Y axis and about the Z axis. Alternatively, for example, the stage mover assembly 40 could be designed to move the stage 38 with less than three degrees of freedom, or more than three degrees of freedom. The stage mover assembly 40 can include one or more movers, such as linear motors, rotary motors, voice coil motors, electromagnetic movers, a planar motors, or some other force mover.

Further, in photolithography systems, when linear motors (see U.S. Pat. Nos. 5,623,853 or 5,528,118) are used in a wafer stage or a mask stage, the linear motors can be either an air levitation type employing air bearings or a magnetic levitation type using Lorentz force or reactance force. Additionally, the stage could move along a guide, or it could be a guideless type stage that uses no guide. As far as is permitted, the disclosures in U.S. Pat. Nos. 5,623,853 and 5,528,118 are incorporated herein by reference.

Alternatively, one of the stages could be driven by a planar motor, which drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage.

Movement of the stages as described above generates reaction forces that can affect performance of the photolithography system. Reaction forces generated by the wafer (substrate) stage motion can be mechanically transferred to the floor (ground) by use of a frame member as described in U.S. Pat. No. 5,528,100 and published Japanese Patent Application Disclosure No. 8-136475. Additionally, reaction forces generated by the reticle (mask) stage motion can be mechanically transferred to the floor (ground) by use of a frame member as described in U.S. Pat. No. 5,874,820 and published Japanese Patent Application Disclosure No. 8-330224. As far as is permitted, the disclosures in U.S. Pat. Nos. 5,528,100 and 5,874,820 and Japanese Patent Application Disclosure No. 8-330224 are incorporated herein by reference.

The measurement system 22 monitors movement of the reticle 26 and the wafer 28 relative to the optical assembly 16 or some other reference. With this information, the control system 24 can control the reticle stage assembly 18 to precisely position the reticle 26 and the wafer stage assembly 20 to precisely position the wafer 28. For example, the measurement system 22 can utilize multiple laser interferometers, encoders, and/or other measuring devices.

The control system 24 is connected to the reticle stage assembly 18, the wafer stage assembly 20, and the measurement system 22. The control system 24 receives information from the measurement system 22 and controls the stage mover assemblies 18, 20 to precisely position the reticle 26 and the wafer 28. The control system 24 can include one or more processors and circuits.

A photolithography system (an exposure apparatus) according to the embodiments described herein can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

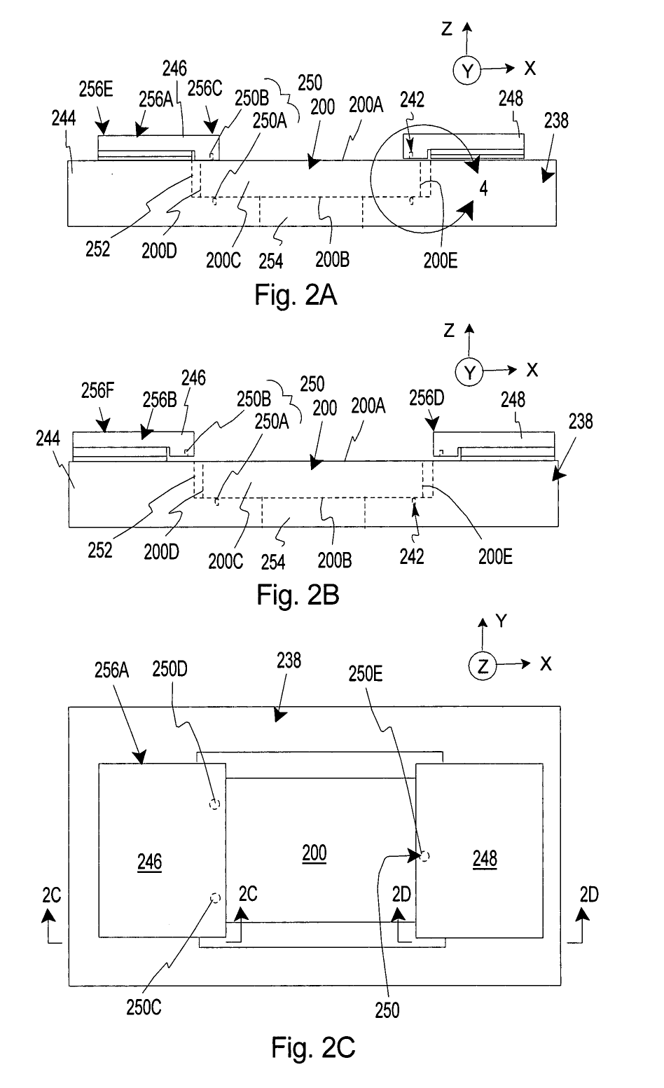

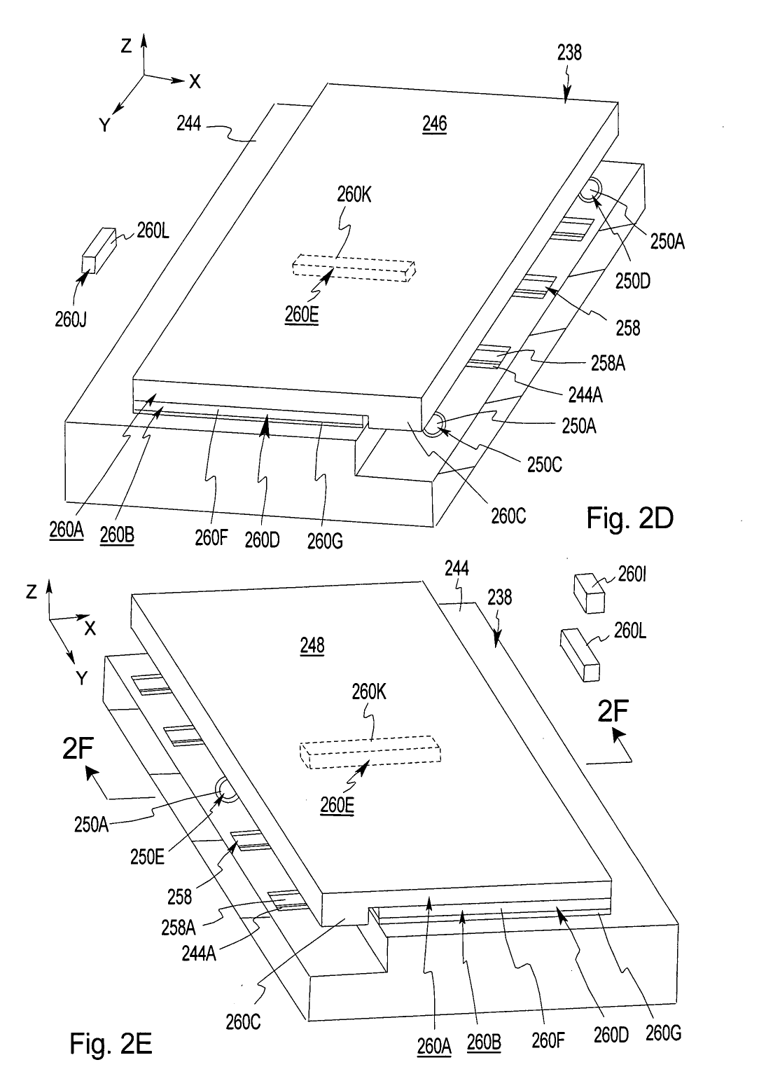

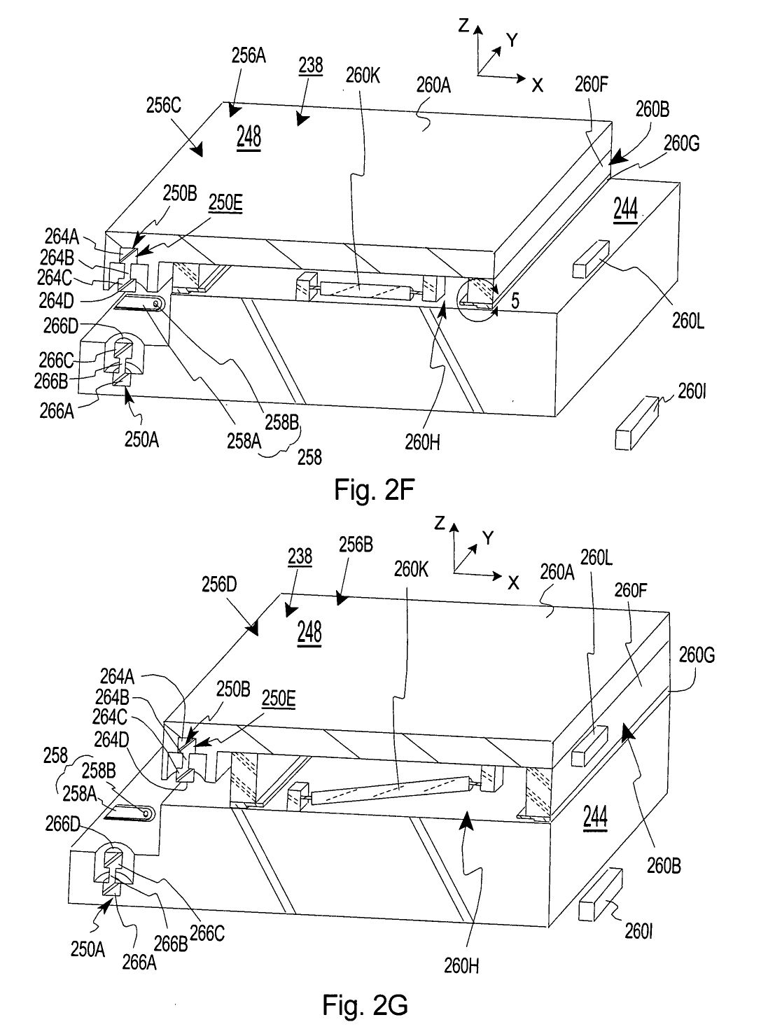

FIGS. 2A and 2B are simplified side views of a work piece 200 (illustrated in phantom) and a stage 238 that is used to retain a work piece 200. For example, the stage 238 can be used as part of the reticle stage assembly 18 in the exposure apparatus 10 of FIG. 1. In this embodiment, the work piece 200 is a reticle 26 and the stage 238 securely retains the reticle 26. Alternatively, the stage 238 can be used as part of the wafer stage assembly 20 in the exposure apparatus 10 in FIG. 1. In this embodiment, the work piece 200 is a wafer 28 and the stage 238 securely retains the wafer 28.

Still alternatively, the stage 238 can be used to retain other types of work pieces 200 during manufacturing and/or inspection, to retain a device under an electron microscope (not shown), or to retain a device during a precision measurement operation (not shown).

In this embodiment, the work piece 200 is generally rectangular shaped and includes a top 200A, a bottom 200B, and four sides, namely a front side 200C, a left side 200D, a right side 200E, and a back side (not shown in FIGS. 2A and 2B). Alternatively, the work piece 200 can have another configuration.

The stage 238 includes a stage housing 244, a first movable section 246, a second movable section 248, and a device holder 242 that includes one or more support pairs 250 (illustrated in phantom) that engage the work piece 200 and that secure the work piece 200 to the stage housing 244. The design of these components can vary. Further, one or more of these components can be optional.

The stage housing 244 supports the other components of the stage 238. In FIG. 2A, the stage housing 244 is generally rigid, rectangular plate shaped. Further, the stage housing 244 can include a work piece channel 252 (illustrated in phantom) that receives the work piece 200 and a beam aperture 254 (illustrated in phantom) that allows the energy beam that passes through or that is reflected off of the work piece 200 to be directed at the optical assembly 16 (illustrated in FIG. 1). The design of work piece channel 252 and the beam aperture 254 can vary. In FIG. 2A, the work piece channel 252 and the beam aperture 254 are each generally rectangular shaped.

Suitable materials for the stage housing 244 include rigid materials such LTEM ceramics, or LTEM glass-ceramics.

The first movable section 246 and the second movable section 248 are movable relative to the stage housing 244 between a locked position 256A illustrated in FIG. 2A, and an unlocked position 256B illustrated in FIG. 2B. In the locked position 256A, a portion of each movable section 246, 248 is positioned over the work piece 200 and the work piece channel 252, and the movable sections 246, 248 cooperate with the one or more support pairs 250 to retain the work piece 200. In the unlocked position 256B, the movable sections 246, 248 are not positioned over the work piece 200 and work piece channel 252, and the work piece 200 can be removed from and/or added to the work piece channel 252. The movable sections 246, 248 are described in more detail below.

The support pairs 250 cooperate to engage the top 200A and the bottom 200B of the work piece 200 to secure and clamp the work piece 200 therebetween. The design and number of support pairs 250 can be varied pursuant to the teachings provided herein. In the embodiment illustrated in FIGS. 2A and 2B, each of the support pairs 250 includes a lower support 250A that is secured to the stage housing 244, and an upper support 250B that is secured to one of the movable sections 246, 248. It should be noted that the terms upper and lower are used merely for convenience and that the orientation of these components can be different than that illustrated in FIGS. 2A and 2B. The support pairs 250 are described in more detail below.

In certain embodiments, during movement of the movable sections 246, 248 from the locked position 256A to the unlocked position 256B, a portion of each of the movable sections 246, 248 is first moved upward (along the Z axis) from a clamped Z position 256C (illustrated in FIG. 2A) to an unclamped Z position 256D (illustrated in FIG. 2B) so that the upper support 250B no longer contacts the work piece 200. Next, the movable sections 246, 248 are slid (away from each other along the X axis) from an extended X position 256E (illustrated in FIG. 2A) to a retracted X position 256F (illustrated in FIG. 2B) in which the movable sections 246, 248 are positioned away from the work piece 200. In the retracted X position 256F, the movable sections 246, 248 have been moved to provide clearance for loading and unloading of the work piece 200.

Subsequently, during movement of the movable sections 246, 248 from the unlocked position 256B to the locked position 256A, the movable sections 246, 248 are slid (towards each other along the X axis) from the retracted X position 256F to the extended X position 256E in which the movable sections 246, 248 are positioned over the work piece 200. Next, a portion of each of the movable sections 246, 248 is moved downward (along the Z axis) from the unclamped Z position 256D to the clamped Z position 256C so that the upper support 250B contacts the work piece 200 to retain the work piece 200. This design reduces the likelihood of particle generation and/or damage to the work piece 200 because the upper support 250B has only normal contact with the work piece 200 and the upper support 250B is not dragged across the work piece 200.

FIG. 2C is a simplified top view of the work piece 200 and the stage 238 with the movable sections 246, 248 in the locked position 256A. FIG. 2C illustrates that the stage 238 includes three spaced apart support pairs 250 (illustrated in phantom) that cooperate to clamp the work piece 200 at three spaced apart locations. With this design, the work piece 200 is supported in a somewhat kinematic fashion. These support pairs 250 are labeled as a first support pair 250C, a second support pair 250D, and a third support pair 250E for convenience. In this embodiment, a portion of the first support pair 250C and a portion of the second support pair 250D is secured to the first movable section 246, and a portion of the third support pair 250E is secured to the second movable section 248.

FIG. 2D is a cut-away view taken on line 2D-2D in FIG. 2C without the work piece 200, and FIG. 2E is a cut-away view taken on line 2E-2E in FIG. 2C without the work piece 200. FIG. 2D illustrates a portion of the stage housing 244, the first movable section 246, the lower support 250A of the first support pair 250C, and the lower support 250A of the second support pair 250D. Somewhat similarly, FIG. 2E illustrates a portion of the stage housing 244, the second movable section 248, and the lower support 250A of the third support pair 250E. The design of these components can vary pursuant to the teachings provided herein.

In this embodiment, the first movable section 246 and the second movable section 248 are movable relative to each other and the stage housing 244. In one embodiment, each moveable section 246, 248 includes a section housing 260A, and a section mover assembly 260B. In FIGS. 2D and 2E, each of the section housings 260A is rigid and generally flat, rectangular plate shaped. Further, each section housing 260A includes a generally rectangular shaped lip 260C that extends along the edge of the respective section housing 260A and that faces the work piece 200.

Suitable materials for each section housing 260A includes rigid materials such LTEM ceramics, LTEM glass-ceramics, or Invar.

Each section mover assembly 260B moves the respective section housing 260A up and down along the Z axis (perpendicular to the top 200A of the work piece 200) and back and forth along the X axis (parallel to the top 200A of the work piece 200). The design of each section mover assembly 260B can vary pursuant to the teachings provided herein. In one embodiment, each section mover assembly 260B includes a Z mover 260D that moves the respective section housing 260A up and down along the Z axis, and an X mover 260E that moves the respective section housing 260A back and forth along the X axis. Alternatively, each section mover assembly 260B can include a single mover (not shown) that moves the respective section housing 260A along the Z axis and along the X axis.

In certain embodiments, each section mover assembly 260B is designed to minimize the amount of particles generated during movement of the section housings 260A. Each section mover assembly 260B can include one or more onboard or external actuators. Further, the actuators can be pneumatic, magnetic, or electric.

In one embodiment, each Z mover 260D includes a resilient member 260F, and a seal 260G. In this embodiment, each resilient member 260F is generally rectangular ring shaped, has a generally rectangular shaped cross-section, and is positioned under the respective section housing 260A. Further, the seal 260G is generally rectangular ring shaped, has a generally rectangular shaped cross-section, and is positioned under the respective resilient member 260F and above the stage housing 244. For each movable section 246, 248, the resilient member 260F and the seal 260G cooperate with the respective section housing 260A and the stage housing 244 to define a chamber 260H (illustrated in FIG. 2F).

Additionally, in one embodiment, the Z movers 260D include a common vacuum source 2601 (illustrated in FIG. 2E) that is in fluid communication with the chamber 260H of each movable section 246, 248. Alternatively, for example, each of the movable sections 246, 248 can include a separate vacuum source. The operation of the Z mover 260D of the second movable section 248 is described in more detail below.

In one embodiment, for each movable section 246, 248, the X mover 260E includes a X housing mover 260J that moves the respective section housing 260A along the X axis away from the other section housing 260A, and a return device 260K (illustrated in phantom) that moves the respective section housing 260A along the X axis toward the other section housing 260A. In this embodiment, the X housing mover 260J includes an electromagnet 260L that is positioned away from the respective section housing 260A. With this embodiment, when activated, the electromagnet 260L attracts the respective section housing 260A and urges the respective section housing 260A along the X axis toward the electromagnet 260L and away from the other section housing 260A. With this design, the electromagnet 260L can move the respective section housing 260A in one direction along the X axis in a non-contact fashion.

In this embodiment, the electromagnets 260L are positioned away from the stage 238. For example, the electromagnets 260L can be secured to the apparatus frame 12 (illustrated in FIG. 1). With this design, the stage 238 can be moved to be near the electromagnets 260L when loading and unloading the stage 238.

The return device 260K urges the respective section housing 260A in the opposite direction along the X axis. With this design, when the electromagnets 260L are turned off, the return device 260K moves the respective section housing 260A in the opposite direction along the X axis. In one embodiment, the return device 260K is a spring or other resilient member.

Alternatively, for example, the electromagnets 260L and/or the return devices 260K can be replaced with a linear type actuator, or a pneumatic type actuator.

Additionally, in the embodiment illustrated in FIGS. 2D and 2E, the stage 238 can include one or more spaced apart resilient supports 258 that additionally support the left side 200D and the right side 200E of the work piece 200. These resilient supports 258 inhibit sagging of the left side 200D and the right side 200E of the work piece 200. Stated in another fashion, the one or more spaced apart resilient supports 258 provide soft support to counter the effects of gravity on the work piece 200.

For example, the one or more resilient supports 258 can apply a known upward force on the respective side of the work piece 200. In alternative, non-exclusive embodiments, each of the resilient supports 258 provides an upward force of approximately 0.2, 0.25, 0.3, 0.33, 0.35, or 0.4 Newtons on the work piece 200. However, the resilient supports 258 can be designed to provide other forces than these examples.

With this design, the resilient supports 258 lessen the effects of gravity on distortion on the work piece 200, and the resilient supports 258 allow for a controlled, known shape, and repeatable distortion of the work piece 200. For example, with the resilient supports 258, the work piece 200 distorts to a known, relatively simple second order/parabolic shape (when viewed in the XZ plane). This shape can be easily compensated for by adjusting one or more of the lenses of the illumination optical assembly 34 (illustrated in FIG. 1) and/or optical assembly 16 (illustrated in FIG. 1).

Further, in certain embodiments, the resilient supports 258 reduce distortion of the work piece 200 caused by any flatness mismatch between the seats of the support pairs 250 and the work piece 200.

If the stage 238 is designed without the resilient supports 258, the work piece 200 is only supported by the three spaced apart support pairs 250A, 250B, 250C. In certain embodiments, with the work piece 200 supported at only three points, gravity on the work piece 200 can cause the work piece 200 to distort to a complicated shape which cannot be easily compensated for.

The design of resilient supports 258 can vary. In one embodiment, each of the resilient supports 258 is a blade spring 258A (e.g. a flat piece of spring steel) positioned in a blade housing aperture 244A in the stage housing 244, and the blade spring 258A cantilevers away from the stage housing 244. Alternatively, each resilient support 258 can be another type of spring or resilient support.

In certain embodiments, the resilient supports 258 are compliant in all axes except along the Z axis.

The number of resilient supports 258 can also vary. FIG. 2D illustrates that the left side of the stage 238 includes three spaced apart resilient supports 258 positioned between the first support pair 250C and the second support pair 250D. Further, FIG. 2E illustrates that the right side of the stage 238 includes four spaced apart resilient supports 258, with two resilient supports 258 positioned on each side of the third support pair 250E. Alternatively, the left side or the right side of the stage 238 can include more than the number of resilient supports 258 illustrated in FIGS. 2D and 2E.

Additionally, the resilient supports 258 can be designed so that the friction force between the resilient supports 258 and the work piece 200 is relatively small, so that some minute sliding of the work piece 200 relative to the resilient supports 258 can occur without significant particle generation. This can be achieved by using several resilient supports 258, to reduce the contact force between the resilient supports 258 and the work piece 200.

FIG. 2F is a simplified cut-away view of a portion of the stage 238 with the second movable section 248 in the locked position 256A and FIG. 2G is a simplified cut-away view of the portion of the stage 238 with the second movable section 248 in the unlocked position 256B (exaggerated for clarity). These Figures illustrate the section mover assembly 260B of the second movable section 248 in more detail. More specifically, these Figures illustrate the resilient member 260F and the seal 260G cooperate with the section housing 260A and the stage housing 244 to define the chamber 260H. In this embodiment, a vacuum pulled in the chamber 260H urges the section housing 260A downward along the Z axis and the resilient member 260F urges the section housing 260A upward along the Z axis. With this design, when the vacuum source 2601 pulls a vacuum in the chamber 260H, the resilient member 260F compresses and the section housing 260A is moved downward along the Z axis towards the stage housing 244 to the clamped Z position 256C. Alternatively, when the vacuum source 2601 does not pull a vacuum in the chamber 260H, the clamping force is removed and the resilient member 260F urges the section housing 260A upward along the Z axis away from the stage housing 244 to the unclamped Z position 256D. With this design, the Z mover 260D can be used to selectively move the section housing 260A is up and down along the Z axis between the Z positions 256C, 256D.

As an example, the resilient member 260F can be made of a compliant material such as neoprene rubber. With this design, the resilient member 260F provides a spring like force to lift the section housing 260A away from the work piece 200.

In certain embodiments, the present invention provides a relatively large vacuum type clamping force to securely retain the work piece 200. For example, in one embodiment, each movable section 246, 248 can provide an effective piston area of approximately 5500 mm². In this example, with vacuum of approximately 60 kPa, the two movable sections 246, 248 can apply a clamping force of approximately 300N. As a result thereof, the work piece 200 can be selectively retained by the stage 238.

The seal 260G seals the chamber 260H. Further, the seal 260G slides along the stage housing 244 during movement of the movable section 246, 248 along the X axis. In certain embodiments, the chamber 260H can be pressurized to levitate the movable section 246, 248 and the respective seal 260G to reduce wear from sliding contact.

Additionally, or alternatively, the seal 260G can be made of a relatively low wear material to reduce wear from sliding contact between the seal 260G and the stage housing 244. A suitable material for the seal 260G is a material sold under the trademark “Teflon”. Further, the seal 260G can be designed so that the contact areas are substantially contained within the chamber 260H. With this design, particles generated by the movement of the seal 260G are contained within the chamber 260H.

In summary, the present invention uses a vacuum actuated clamp to hold the work piece 200. The clamp force is transferred to the work piece 200 via the three support pairs 250. Further, the clamping mechanism can be opened and closed with minimal particle generation or wear. Further, the clamp design includes relatively few parts.

These Figures also illustrate the return device 260K in more detail. In this embodiment, the return device 260K includes a first end that is fixedly secured to the stage housing 244 and a second end that is fixedly secured to the respective movable section 246, 248.

As provided above, when activated, the electromagnet 260L attracts the respective section housing 260A and moves the section housing 260A along the X axis toward the electromagnet 260L. The return device 260K urges the section housing 260A in the opposite direction along the X axis. With this design, when the electromagnet 260L is turned off, the return device 260K moves the section housing 260A in the opposite direction along the X axis.

Alternatively, for example, the electromagnet 260L and the return device 260K can be replaced with a linear type actuator.

FIGS. 2F and 2G illustrate one of the resilient supports 258 in more detail. More specifically, in this embodiment, the blade spring 258A extends generally parallel to the work piece 200 and the resilient support 258 includes a contact pad 258B that extends upward from the blade spring 258A to engage the bottom of the work piece 200. The contact pad 258B provides a relatively small engagement surface that engages the work piece 200 so that some minute sliding of the work piece 200 relative to the resilient supports 258 can occur without significant particle generation.

FIG. 2F and 2G also illustrate one of the support pairs 250, namely the third support pair 250E in more detail. The first and second support pairs 250C, 250D can be similar in design as the third support pair 250E. Alternatively, the first and second support pairs 250C can have a different design than the third support pair 250E. . In this embodiment, the upper support 250B is generally cylindrical shaped and includes (i) a generally cylindrical shaped attachment region 264A that is secured to the section housing 260A, (ii) a generally cylindrical shaped connector region 264B that cantilevers away from the attachment region 264A, and (iii) a generally cylindrical shaped seat region 264C that cantilevers away from the attachment region 264A. The seat region 264C includes a seat contact 264D that is positioned lower along the Z axis than the section housing 260A so that the seat contact 264D engages the work piece 200 and the section housing 260A does not engage the work piece 200.

Somewhat similarly, the lower support 250A is generally cylindrical shaped and includes (i) a generally cylindrical shaped attachment region 266A that is secured to the stage housing 244, (ii) a generally cylindrical shaped connector region 266B that cantilevers away from the attachment region 266A, and (iii) a generally cylindrical shaped seat region 266C that cantilevers away from the attachment region 266A. The seat region 266C includes a seat contact 266D that is positioned higher along the Z axis than that the stage housing 244 at that area so that the seat contact 266D engages the work piece 200 and the stage housing 244 does not engage the work piece 200.

In one example, each seat contact 264D, 266D has an area of approximately 3.3 mm. The relatively small seat contact 264D, 266D minimize contact-tensile stress in the reticle.

In one embodiment, each of the supports 250A, 250B is rotationally compliant in pitch and roll. This reduces any moments caused by mismatch and reduces distortion of the work piece 200. In one embodiment, the supports 250A, 250B are similar in design and flexibility. Alternatively, the supports 250A, 250B can be different in design and flexibility. Further, the flexibility of the first and second support pairs 250C, 250D can be different than the flexibility of the third support pair 250E.

In certain embodiments, the supports 250A, 250B need to be stiff along the X, Y, and Z axes and compliant about the X and Y axes. Further, it may be necessary for the upper support 250B to be compliant along the X and Y axes to ensure the clamp mass is not coupled to the work piece mass.

Additionally, in certain embodiments, misalignment between the upper support 250B and the lower support 250A of one or more of the support pairs 250 can cause moments on the work piece 200 and greater correctable and/or non-correctable distortion of the work piece 200. Accordingly, it can be important to ensure repeatable alignment between the upper support 250B and the lower support 250A of each of the support pairs 250.

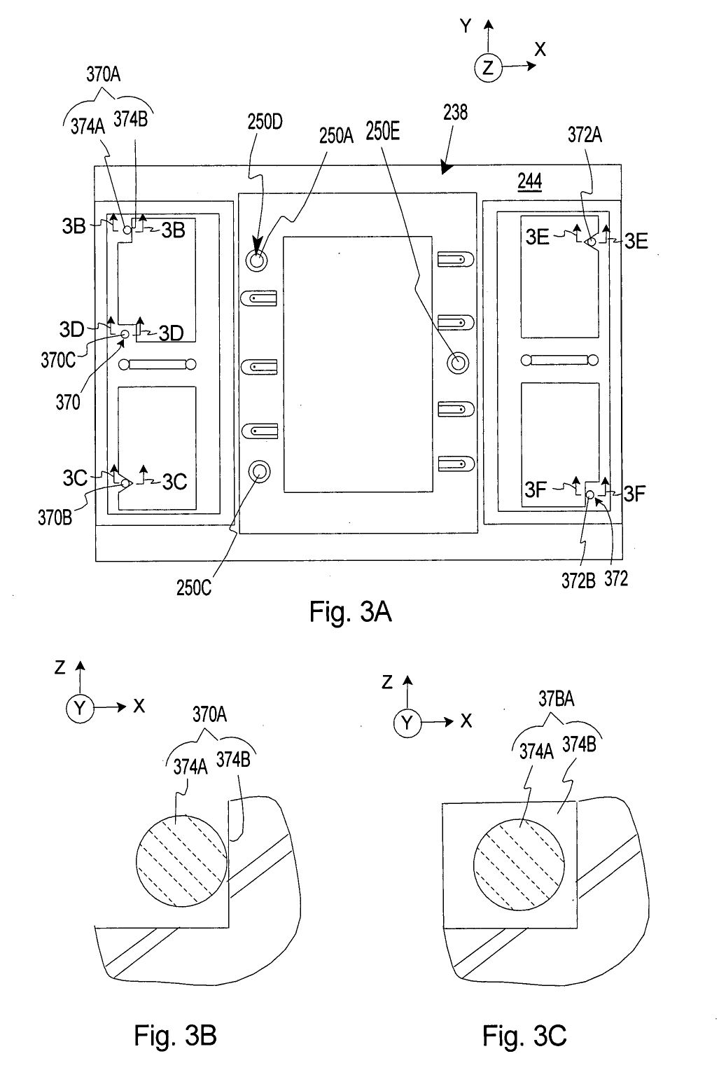

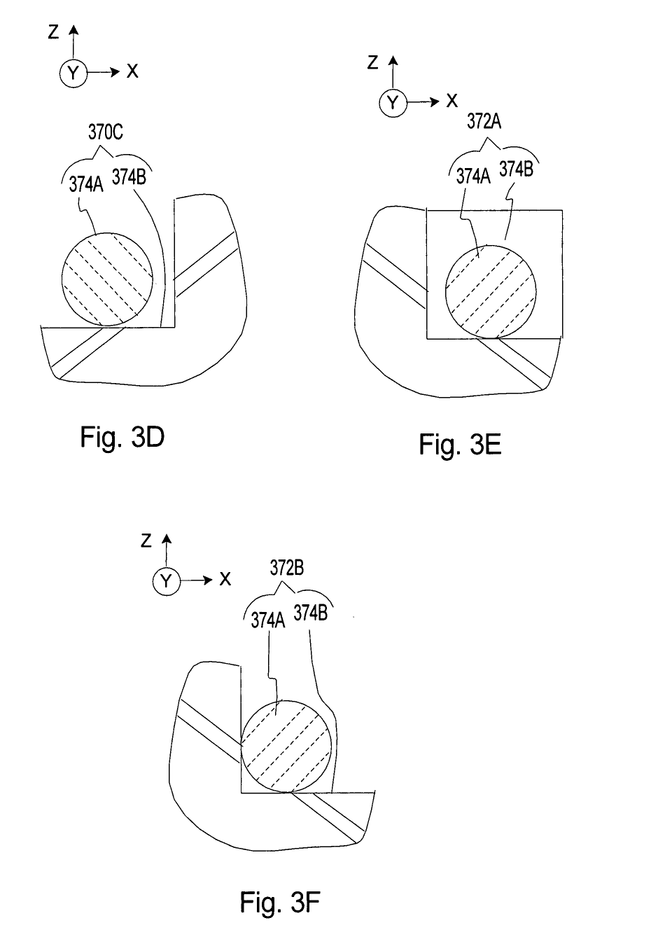

FIG. 3A is a top plan view of a portion of the stage 238 without the section housing 260A of the movable sections 246, 248 to illustrate one way to repeatable align the support pairs 250C, 250D, 250E (only the lower support 250A of each is illustrated in FIG. 3A). More specifically, in this embodiment, the stage 238 include a first alignment assembly 370 for aligning the section housing 260A of the first movable section 246 and a second alignment assembly 372 for aligning the section housing 260A of the second movable section 248. The design of each of the alignment assemblies 370, 372 can vary pursuant to the teachings provided herein.

In one embodiment, the first alignment assembly 370 (i) aligns the first section housing 260A along the X axis, along the Y axis and about the Z axis when the first section housing 260A is moved from the retracted X position 256F (illustrated in FIG. 2B) to the extended X position 256E (illustrated in FIG. 2A); and (ii) aligns the first section housing 260A along the Z axis, about the X axis, and about the Y axis when the section housing 260A is moved from the unclamped Z position 256D (illustrated in FIG. 2B) to the clamped Z position 256C (illustrated in FIG. 2A).

In FIG. 3A, the first alignment assembly 370 includes (i) an X aligner 370A and an XY aligner 370B that cooperate to align the first section housing 260A along the X axis, along the Y axis and about the Z axis when the first section housing 260A is moved from the retracted X position 256F to the extended X position 256E. Further, the first alignment assembly 370 can include a Z aligner 370C that cooperates with the first and second support pairs 250C, 250D to align the first section housing 260A along the Z axis, about the Y axis, and about X axis when the first section housing 260A is moved from the unclamped Z position 256D to the clamped Z position 256C.

Further, in FIG. 3A, the second alignment assembly 372 includes an X YZ aligner 372A and an XZ aligner 372B (i) that cooperate to align the second section housing 260A along the X axis, along the Y axis and about the Z axis when the second section housing 260A is moved from the retracted X position 256F to the extended X position 256E and (ii) that cooperate with the third support pair 250E to align the second section housing 260A along the Z axis, about the Y axis, and about X axis when the second section housing 260A is moved from the unclamped Z position 256D to the clamped Z position 256C.

Alternatively, the alignment assemblies 320, 372 can be designed with more or fewer aligners than that illustrated in FIG. 3A.

In this embodiment, each aligner 370A, 370B, 370C, 372A, 372B includes a first aligner component 374A that is fixedly secured to the respective section housing 260A (not shown in FIG. 3A) and a second aligner component 374B that is secured to the stage housing 244 and that engages the respective first aligner component 374A. The design of each of these components can vary to achieve the desired degrees of alignment.

In one embodiment, one or both of the aligner components 374A, 374B are relatively hard and include a relatively low friction surface to provide a highly consistent engagement between the aligner components 374A, 374B and precise and easily repeatable alignment.

FIG. 3B is a cut-away view of the X aligner 370A. In this embodiment, the first aligner component 374A is a spherical ball (e.g. a rounded area) that is fixedly secured to the first section housing 260A (not shown in FIG. 3B), and the second aligner component 374B is a flat wall that engages the spherical ball to inhibit movement and align the first section housing 260A along the X axis when the first section housing 260A is moved from the retracted X position 256F to the extended X position 256E.

FIG. 3C is a cut-away view of the XY aligner 370B. In this embodiment, the first aligner component 374A is a spherical ball (e.g. a rounded area) that is fixedly secured to the first section housing 260A (not shown in FIG. 3C), and the second aligner component 374B includes a pair of flat walls (only one is shown in FIG. 3C) oriented in a “V” configuration. With this design, the spherical ball engages the flat walls to inhibit movement and align the first section housing 260A along the X axis and along the Y axis when the first section housing 260A is moved from the retracted X position 256F to the extended X position 256E.

It should be noted that the X aligner 370A and the XY aligner 370B cooperate to also align the first section housing 260A about the Z axis.

FIG. 3D is a cut-away view of the Z aligner 370C. In this embodiment, the first aligner component 374A is a spherical ball (e.g. a rounded area) that is fixedly secured to the first section housing 260A (not shown in FIG. 3D), and the second aligner component 374B is a flat wall that engages the spherical ball to inhibit movement and align the first section housing 260A along the Z axis. In this embodiment, the first and second support pairs 250C, 250D also align the first section housing 260A along the Z axis. With this design, the Z aligner 370C cooperates with the first and second support pairs 250C, 250D to align the first section housing 260A along the Z axis, about the Y axis, and about X axis when the first section housing 260A is moved from the unclamped Z position 256D to the clamped Z position 256C.

FIG. 3E is a cut-away view of the XYZ aligner 372A. In this embodiment, the first aligner component 374A is a spherical ball (e.g. a rounded area) that is fixedly secured to the second section housing 260A (not shown in FIG. 3E), and the second aligner component 374B includes a pair of flat walls (only one is shown in FIG. 3E) oriented in a “V” configuration and a bottom wall. With this design, (i) the spherical ball engages the flat walls to inhibit movement and align the second section housing 260A along the X axis and along the Y axis when the second section housing 260A is moved from the retracted X position 256F to the extended X position 256E, and (ii) the spherical ball engages the bottom wall to inhibit movement and align the second section housing 260A along the Z axis when the second section housing 260A is moved from the unclamped Z position 256D to the clamped Z position 256C.

FIG. 3F is a cut-away view of the XZ aligner 372B. In this embodiment, the first aligner component 374A is a spherical ball (e.g. a rounded area) that is fixedly secured to the second section housing 260A (not shown in FIG. 3E), and the second aligner component 374B includes a pair of flat walls oriented in a “L” configuration. With this design, (i) the spherical ball engages the vertical flat wall to inhibit movement and align the second section housing 260A along the X axis when the second section housing 260A is moved from the retracted X position 256F to the extended X position 256E, and (ii) the spherical ball engages the bottom flat wall to inhibit movement and align the second section housing 260A along the Z axis when the second section housing 260A is moved from the unclamped Z position 256D to the clamped Z position 256C.

With this design, the XYZ aligner 372A, and the XZ aligner 372B cooperates with the third support pair 250E to align the second section housing 260A along the Z axis, about the Y axis, and about X axis.

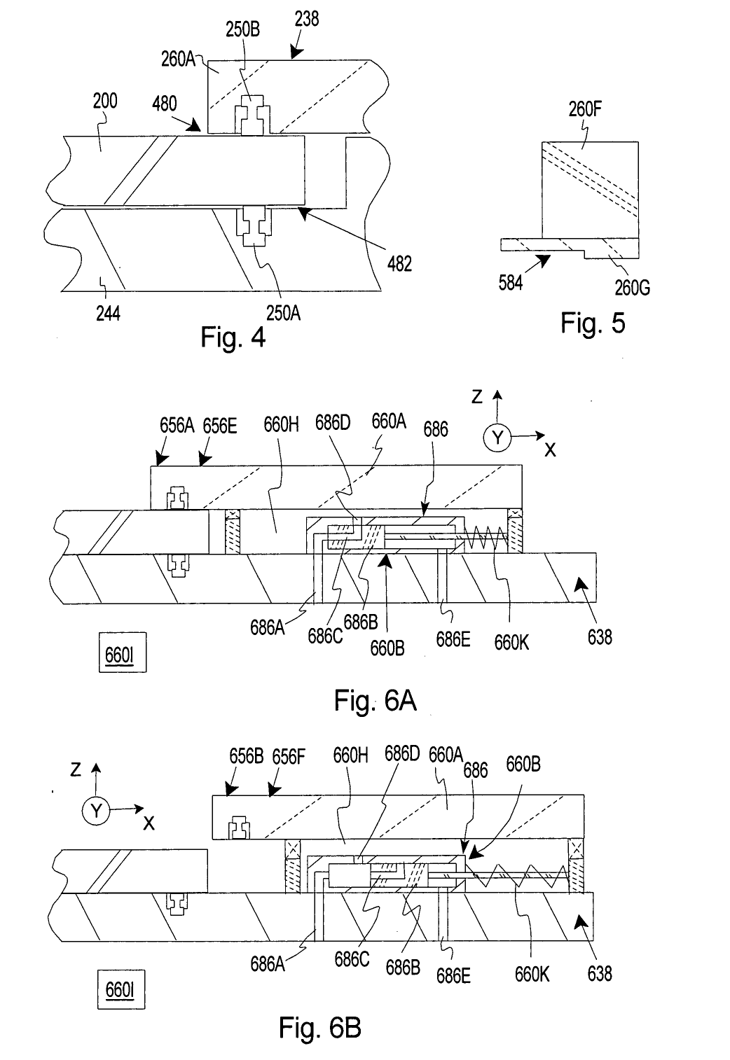

It should be noted that the aligner components 374A, 374B can be switched. Further, the spherical ball could be replaced with a curved surface. . FIG. 4 is a simplified enlarged cross-section view taken on line 4-4 in FIG. 2A. FIG. 4 illustrates that the upper support 250B and the lower support 250A support the work piece 200 there between and the stage 238 is designed to provide squeeze film type damping of the work piece 200 to reduce vibration in the work piece 200 and reduce unwanted errors. In this embodiment, the supports 250A, 250B retain the work piece 200 with a slight upper gap 480 between the work piece 200 and the section housing 260A, and a slight lower gap 482 between the work piece 200 and the stage housing 244. The gaps 480, 482 are filed with fluid, e.g. air that each provide squeeze film damping.

The size of the gaps 480, 482 is precisely controlled by the positions of the supports 250A, 250B relative to the rest of the stage 238. In alternative, non-exclusive embodiments, each of the gaps 480, 482 is between approximately 5 and 20 micrometers.

FIG. 5 is an enlarged cut-away view of the seal 260G and the resilient member 260F. This Figure illustrates that the seal 260G can include a cut-out area 584. With this design, when a vacuum is pulled in the chamber 260H (illustrated in FIG. 2F), the vacuum force is applied directly to the cut-out area 584 of the seal 260G to promote a good seal to the stage housing 244 (illustrated in FIG. 2F).

FIGS. 6A and 6B are alternative cut-away views of another embodiment of a stage 638 that illustrate another embodiment of a section mover assembly 660B. In this embodiment, an internal pneumatic piston assembly 686 is used instead of the electromagnet to move the section housing 660A along the X axis from the extended X position 656E (illustrated in FIG. 6A) to the retracted X position 656F (illustrated in FIG. 6B). Further, in this embodiment, the return device 660K, e.g. a spring is used to move the section housing 660A along the X axis in the opposite direction.

In one embodiment, the internal pneumatic piston assembly 686 is controlled by the same vacuum source 6601 that is used to move the section housing 660A up and down along the Z axis. Referring initially to FIG. 6B, to move the section housing 660A from the unlocked position 656B to the locked position 656A, a vacuum is pulled at an inlet 686A to the internal pneumatic piston assembly 686. This causes a piston 686B of the internal pneumatic piston assembly 686 to move the section housing 660A along the X axis. Once the section housing 660A has moved along the X axis, as illustrated in FIG. 6A, a port 686C through the piston 686B is aligned with an aperture 686D in the piston wall so that the chamber 660H is subjected to a vacuum that moves the section housing 660A downward along the Z axis.

Referring initially to FIG. 6A, to move the section housing 660A from the locked position 656A to the unlocked position 656B, the vacuum is removed from inlet 686A to the piston assembly 686 and the chamber 660H. This causes the section housing 660A to move upward along the Z axis. Further, with the vacuum removed from the internal pneumatic piston assembly 686, the return device 660K moves the section housing 660A along the X axis in the opposite direction.

It should be noted that an outlet 686E to the piston assembly 686 is at a pressure that is greater than the vacuum pressure. For example, the outlet 686E can be at atmospheric pressure.

The vacuum source 6601 can be connected with one or more electronic valves to control the pressure in the internal pneumatic piston 686 and the chamber 660H.

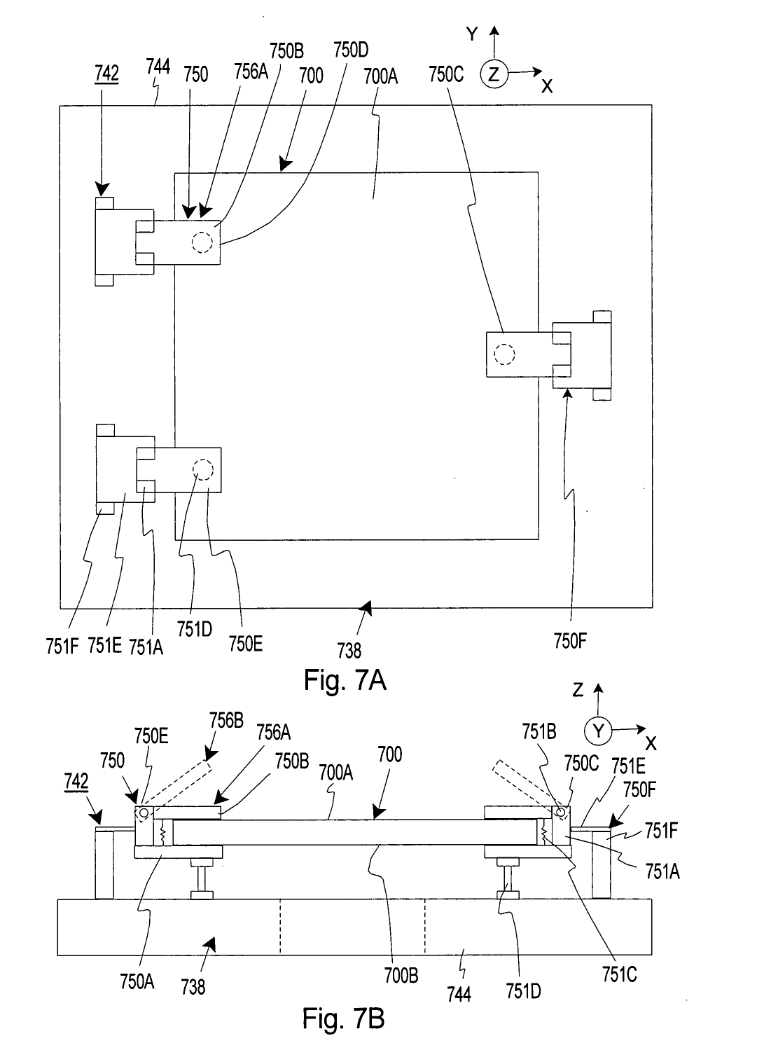

FIG. 7A is a simplified top plan view and FIG. 7B is a simplified side plan view of a work piece 700 and another embodiment of a device stage 738 that retains the work piece 700. For example, the stage 738 can be used as part of the reticle stage assembly 18 or the wafer stage assembly 20 in the exposure apparatus 10 in FIG. 1.

In this embodiment, the work piece 700 is again generally rectangular shaped and includes the top 700A and bottom 700.B.

The stage 738 includes a stage housing 744, and a device holder 742 that includes one or more support pairs 750 that engage the work piece 700 and that secure the work piece 700 to the stage housing 744.

The stage housing 744 supports the other components of the stage 738. In this embodiment, the stage housing 744 is generally rectangular plate shaped and is somewhat similar in design to the stage housing 244 described above without the work piece channel 252.

The support pairs 750 cooperate to engage the top 700A and the bottom 700B of the work piece 700 to secure and clamp the work piece 700 there between. The design and number of support pairs 750 can be varied pursuant to the teachings provided herein. In the embodiment illustrated in FIGS. 7A and 7B, each of the support pairs 750 includes a lower support 750A, an upper support 750B, and a support connector assembly 750F.

The lower support 750A and the upper support 750B of each support pair 750 cooperate to clamp the work piece 700 there between. In FIGS. 7A and 7B, each of the supports 750A, 750B is generally flat, rectangular plate shaped. The lower support 750A is positioned below the work piece 700 and the upper support 750B is positioned above the work piece 700. It should be noted that the terms upper and lower are used merely for convenience and that the orientation of these components can be different than that illustrated in FIGS. 7A and 7B.

The support connector assembly 750F for each support pair 750 (i) connects the upper support 750B to the lower support 750A, (ii) allows the upper support 750B to move relative the lower support 750A between the locked position 756A and the unlocked position 756B (illustrated in phantom in FIG. 7B), (iii) and connects the supports 750A, 750B to the stage housing 744. The design of the support connector assembly 750F can vary pursuant to the teachings provided herein.

In FIGS. 7A and 7B, the support connector assembly 750F for each support pair 750 includes (i) a connector frame 751A, (ii) a connector pin 751B, (iii) a connector resilient member 751C, (iv) a lower connector 751D, (v) a middle connector 751E, and (vi) a support frame 751F. The design of each of these components can vary and/or one or more of these components can be optional.

The connector frame 751A extends vertically between the upper support 750B and the lower support 750A and maintains these supports 750A, 750B spaced apart. In FIGS. 7A and 7B, the connector frame 751A is generally rectangular plate shaped.

The connector pin 751B extends through an aperture (not shown) in the upper support 750B and an aperture (not shown) in the upper part of the connector frame 751A, and allows the upper support 750B to move (e.g. pivot) relative the lower support 750A between the locked position 756A and the unlocked position 756B.

The connector resilient member 751C urges the upper support 750B to move (e.g. pivot) relative the lower support 750A from the unlocked position 756A to the locked position 756A. Further, the upper support 750B can be manually moved from the locked position 756A to the unlocked position 756A. In FIG. 7B, the connector resilient member 751C extends between the upper support 750B and the lower support 750A for each support pair 750. In this embodiment, the connector resilient member 751C can include a spring or flexible strap. Alternatively, for example, the connector resilient member 751C can be replaced with a rotary motor that moves the upper support 750B relative to the lower support 750A between the positions 756A, 756B.

The lower connector 751D connects the supports 750A, 750B to the stage housing 744 and supports the lower support 750A and the upper support 750B along the Z axis away from and above the stage housing 744. In one embodiment, the lower connector 751D is generally rigid along the Z axis and flexible about and in the X axis, and about and in the Y axis. With this design, the opposed supports 750A, 750B are allowed to concurrently pivot to conform to the work piece 700 to inhibit distortion of the work piece 700, while still maintaining the position of the supports 750A, 750B and the work piece 700 along the Z axis. Stated in another fashion, the lower connector 751D supports the support pair 750 along a first axis (along the Z axis) and allow for movement of the support pair 750 about and in a second axis (the X axis) that is orthogonal to the first axis, and about and in a third axis (the Y axis) that is orthogonal to the first axis and the second axis.

In FIGS. 7A and 7B, the lower connector 751D is somewhat cylindrical shaped. Alternatively, the lower connector 751D can have a different configuration. Suitable materials for the lower connector 751D include a low thermal expansion metal sold under the name Invar by Carpenter; a glass-ceramic material sold under the trademark Zerodur™ by Shchott; a glass-ceramic material sold under the trademark Clearceram™ by Ohara: and a ceramic material sold under the trademark Nexcera™ by Nippon Steel. It should be noted that the lower connectors 751D are illustrated in phantom in FIG. 7A and these lower connectors 751D cooperate to provide three spaced apart supports that support the work piece 700 along the Z axis.

The middle connector 751E connects the supports 750A, 750B to the stage housing 744 via the support frame 751F so that force directed to the stage housing 744 is transferred to the supports 750A, 750B and the work piece 200 so that these components move concurrently. Further, the middle connector 751E allows the supports 750A, 750B to pivot about the X axis and about the Y axis. In this embodiment, the middle connector 751E is generally rigid along the X axis, along the Y axis, and about the Z axis; and generally flexible about the X axis, about the Y axis, and along the Z axis. In FIGS. 7A and 7B, the middle connector 751E is a generally rectangular shaped, relatively thin, membrane that extends between the support frame 751F and the connector frame 751A. Alternatively, the middle connector 751E can have a different configuration than that illustrated in FIGS. 7A and 7B. Suitable materials for the middle connector 751E include a low thermal expansion metal sold under the name Invar by Carpenter; a glass-ceramic material sold under the trademark Zerodur™ by Shchott; a glass-ceramic material sold under the trademark Clearceram™ by Ohara: and a ceramic material sold under the trademark Nexcera™ by Nippon Steel.

The support frame 751F supports the one end of middle connector 751E and maintains the middle connector 751E so that it is substantially aligned with a center of gravity (not shown) along the Z axis of the work piece 700. With this design, forces transferred to the work piece 700 via the middle connector 751E do not cause a moment that could deform the work piece 700. In FIGS. 7A and 7B, the support frame 751F is a generally rigid, rectangular shaped beam.

In the embodiment illustrated in FIGS. 7A and 7B, the stage 738 includes three spaced apart support pairs 750 that cooperate to clamp the work piece 700 at three spaced apart locations. With this design, the work piece 700 is supported in a near three point support along the Z axis that is nearly kinematic fashion. In this embodiment, the three points of support along the Z axis correspond to the three lower connectors 751D.

The support pairs 750 are labeled as a first support pair 750C, a second support pair 750D, and a third support pair 750E for convenience. In this embodiment, that design of each of the support pairs 750C-750E is substantially the same. Alternatively, one or more of the support pairs 750C-750E can have a design that is different from that illustrated in FIGS. 7A and 7B.

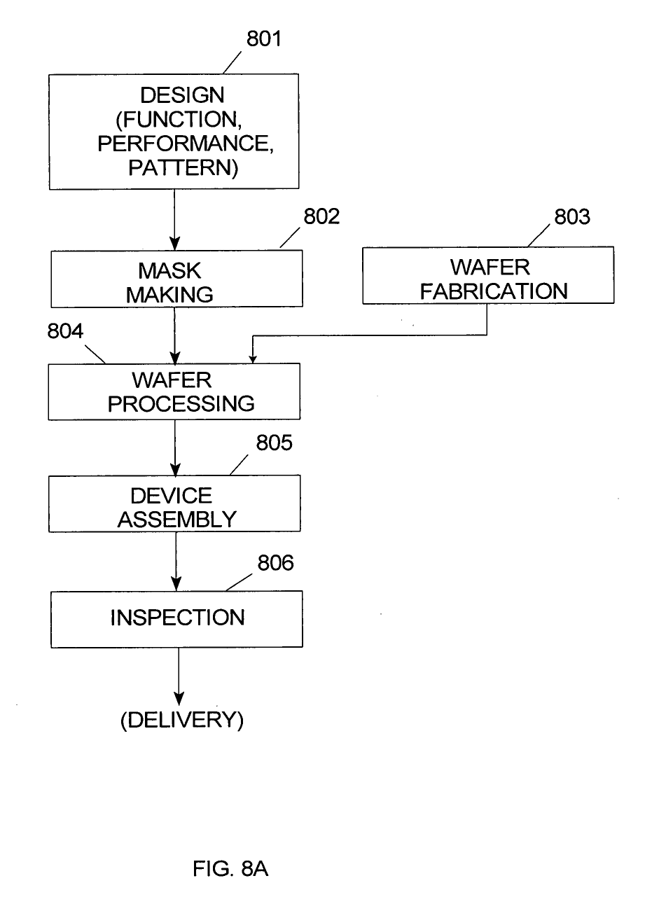

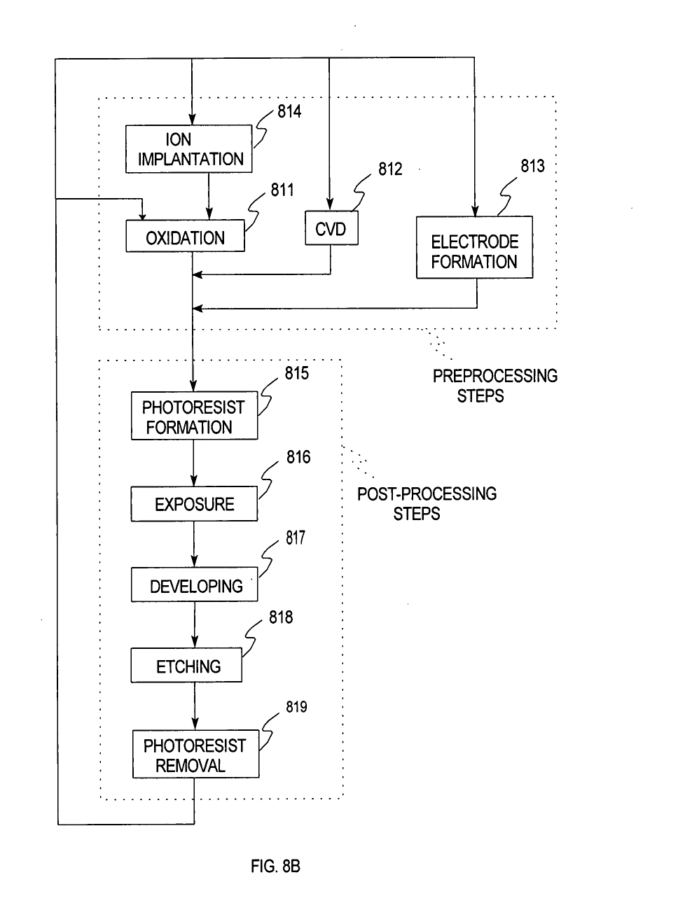

Semiconductor devices can be fabricated using the above described systems, by the process shown generally in FIG. 8A. In step 801 the device's function and performance characteristics are designed. Next, in step 802, a mask (reticle) having a pattern is designed according to the previous designing step, and in a parallel step 803 a wafer is made from a silicon material. The mask pattern designed in step 802 is exposed onto the wafer from step 803 in step 804 by a photolithography system described hereinabove in accordance with the present invention. In step 805, the semiconductor device is assembled (including the dicing process, bonding process and packaging process), finally, the device is then inspected in step 806.

FIG. 8B illustrates a detailed flowchart example of the above-mentioned step 804 in the case of fabricating semiconductor devices. In FIG. 8B, in step 811 (oxidation step), the wafer surface is oxidized. In step 812 (CVD step), an insulation film is formed on the wafer surface. In step 813 (electrode formation step), electrodes are formed on the wafer by vapor deposition. In step 814.(ion implantation step), ions are implanted in the wafer. The above mentioned steps 811-814 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 815 (photoresist formation step), photoresist is applied to a wafer. Next, in step 816 (exposure step), the above-mentioned exposure device is used to transfer the circuit pattern of a mask (reticle) to a wafer. Then in step 817 (developing step), the exposed wafer is developed, and in step 818 (etching step), parts other than residual photoresist (exposed material surface) are removed by etching. In step 819 (photoresist removal step), unnecessary photoresist remaining after etching is removed. Multiple circuit patterns are formed by repetition of these preprocessing and post-processing steps.

While the particular device and method as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A stage assembly that moves a work piece, the stage assembly comprising:
a stage base;
a stage including a stage housing, and a device holder that selectively secures the work piece to the stage housing, the device holder including a first support pair that clamps the work piece there between to couple the work piece to the stage housing; and
a stage mover assembly that moves the stage relative to the stage base.

2. The stage assembly of claim 1 wherein the device holder includes a second support pair that clamps the work piece there between to couple the work piece to the stage housing, the second support pair being spaced apart from the first support pair.

3. The stage assembly of claim 2 wherein the device holder includes a third support pair that clamps the work piece there between to couple the work piece to the stage housing, the third support pair being spaced apart from the first support pair and the second support pair.

4. The stage assembly of claim 1 wherein the stage includes a first movable section that is movable relative to the stage housing, and wherein the first support pair includes a lower support that is secured to the stage housing and an upper support that is secured to the movable section.

5. The stage assembly of claim 4 wherein the movable section is movable along a first axis to lift the upper support normally away from the work piece and along a second axis to move the upper support from above the work piece.

6. The stage assembly of claim 5 wherein the movable section defines a chamber and wherein a vacuum in the chamber moves the movable section along the first axis to clamp the work piece between the supports of the first support pair.

7. The stage assembly of claim 6 wherein the movable section includes a section housing, a resilient member that urges the section housing along the first axis away from the work piece, and a seal that rests on the stage housing to seal the chamber.

8. The stage assembly of claim 7 wherein the seal slides on the stage housing during movement of the movable section along the second axis.

9. The stage assembly of claim 1 wherein the stage includes a plurality of resilient supports that support the work piece.

10. The stage assembly of claim 9 wherein the work piece includes a first side and a second side and the resilient supports support the work piece near the first side and the second side.

11. The stage assembly of claim 1 wherein the work piece is retained a relatively small fluid gap away from the stage housing with the first support pair so that the work piece experiences squeeze film damping.

12. The stage assembly of claim 11 wherein the stage includes a section housing and the work piece is retained a relatively small fluid gap away from the section housing with the first support pair so that the work piece experiences squeeze film damping.

13. An exposure apparatus including the stage assembly of claim 1.

14. The stage assembly of claim 1 further comprising a connector that supports the first support pair along a first axis and that allows for movement of the first support pair along a second axis that is orthogonal to the first axis.

15. A stage assembly that moves a work piece, the stage assembly comprising:
a stage base;
a stage including a stage housing, a device holder that selectively secures the work piece to the stage housing, and a resilient support that engages the work piece and supports the work piece away from the stage housing; and
a stage mover assembly that moves the stage relative to the stage base.

16. The stage assembly of claim 15 wherein the resilient support inhibits sagging of the work piece near the resilient support.

17. The stage assembly of claim 15 further comprising a plurality of spaced apart resilient supports that support the work piece.

18. The stage assembly of claim 17 wherein the work piece includes a first side and a second side and the resilient supports support the work piece near the first side and the second side.

19. The stage assembly of claim 17 wherein the work piece includes a first side and a second side and the resilient supports support the work piece near the first side and the second side so that the work piece has a generally parabolic shape.

20. The stage assembly of claim 15 wherein the device holder includes a first support pair that clamp the work piece there between to couple the work piece to the stage housing.

21. The stage assembly of claim 20 wherein the work piece is retained a relatively small fluid gap away from the stage housing with the first support pair so that the work piece experiences squeeze film damping.

22. The stage assembly of claim 21 wherein the stage includes a section housing and the work piece is retained a relatively small fluid gap away from the section housing with the first support pair so that the work piece experiences squeeze film damping.

23. An exposure apparatus including the stage assembly of claim 15.

24. A stage assembly that moves a work piece, the stage assembly comprising:
a stage base;
a stage including a stage housing, and a device holder that selectively secures the work piece to the stage housing, the device holder maintaining the work piece a relatively small first fluid gap away from the stage to provide squeeze film type damping of the work piece; and
a stage mover assembly that moves the stage relative to the stage base.

25. The stage assembly of claim 24 wherein the stage includes a section housing and the work piece is retained a relatively small second fluid gap away from the section housing so that the work piece experiences squeeze film damping.

26. The stage assembly of claim 24 wherein the device holder includes a first support pair that clamp the work piece there between to couple the work piece to the stage housing, the first support pair maintaining the first fluid gap and the second fluid gap.

27. The stage assembly of claim 24 wherein the stage includes a plurality of resilient supports that support the work piece.

28. The stage assembly of claim 27 wherein the work piece includes a first side and a second side and the resilient supports support the work piece near the first side and the second side.

29. An exposure apparatus including the stage assembly of claim 24.

30. A reticle stage assembly that moves a reticle, the reticle stage assembly comprising:
a stage base;
a stage including a stage housing, and a device holder that selectively secures the reticle to the stage housing, the device holder including three spaced apart support pairs, each support pair clamping the reticle there between to couple the reticle to the stage housing; and
a stage mover assembly that moves the stage relative to the stage base.

31. The reticle stage assembly of claim 30 wherein the stage includes a first movable section that is movable relative to the stage housing, and a second movable section that is moveable relative to the stage housing and the first movable section, and wherein each support pair includes a lower support that is secured to the stage housing and an upper support, and wherein two of the upper supports are secured to the first movable section and one of the upper supports is secured to the second movable section.

32. The reticle stage assembly of claim 31 wherein each of the movable sections is movable along a first axis to lift the upper supports normally away from the work piece, and along a second axis to move the upper support from above the work piece.

33. The reticle stage assembly of claim 32 wherein each movable section defines a chamber and wherein a vacuum in the chamber moves each movable section along the first axis to clamp the work piece between the supports.

34. The reticle stage assembly of claim 33 wherein each movable section includes a section housing, a resilient member that urges the section housing along the first axis away from the work piece, and a seal that rests on the stage housing to seal the chamber.

35. The reticle stage assembly of claim 30 wherein the reticle includes a first side and a second side and wherein the stage includes a plurality of spaced apart resilient supports that support the reticle near the first side and the second side.

36. The reticle stage assembly of claim 30 wherein the reticle is retained a relatively small first fluid gap away from the stage housing with the support pairs so that the work piece experiences squeeze film damping, and wherein the reticle is retained a relatively small second fluid gap away from the stage with the support pairs so that the reticle experiences squeeze film damping.

37. The reticle stage assembly of claim 30 wherein at least one of the support pairs includes a connector that supports the support pair along a first axis and that allows for movement of the support pair about a second axis that is orthogonal to the first axis.

38. An exposure apparatus including the reticle stage assembly of claim 30.

39. A method for moving a work piece, the method comprising the steps of:
providing a stage base;
retaining the work piece with a stage that includes a stage housing, and a first support pair that selectively secures the work piece to the stage housing with the work piece clamped between the first support pair to couple the work piece to the stage housing; and
moving the stage relative to the stage base with a stage mover assembly.

40. The method of claim 39 wherein the stage includes a second support pair and a third support pair that selectively secures the work piece to the stage housing.

41. The method of claim 39 further comprising the step of supporting the work piece with a plurality of spaced apart resilient supports.

42. The method of claim 39 wherein the first support pair retains the work piece a relatively small fluid gap away from the stage housing with the so that the work piece experiences squeeze film damping.

43. A method for moving a work piece, the method comprising the steps of:
providing a stage base;
retaining the work piece with a stage that includes a stage housing, a device holder that selectively secures the work piece to the stage housing, and a plurality of spaced apart resilient supports that support the work piece to inhibit sagging of the work piece; and
moving the stage relative to the stage base with a stage mover assembly.

44. The method of claim 43 wherein the device holder includes three spaced apart support pairs that secure the work piece to the stage housing.

45. The method of claim 44 wherein the support pairs retain the work piece a relatively small fluid gap away from the stage housing so that the work piece experiences squeeze film damping.

46. A method for moving a work piece, the method comprising the steps of:
providing a stage base;
retaining the work piece with a stage that includes a stage housing, and a device holder that secures the work piece to the stage housing with a relatively small fluid gap away from the stage housing so that the work piece experiences squeeze film damping; and
moving the stage relative to the stage base with a stage mover assembly.

47. The method of claim 46 wherein the device holder includes three spaced apart support pairs that secure the work piece to the stage housing.

48. The method of claim 46 further comprising the step of supporting the work piece with a plurality of spaced apart resilient supports.
